(19) United States
(12) Patent Application Publication
(10) Pub. No.: US 2025/0231479 A1
(43) Pub. Date: Jul. 17, 2025

(54) PHOTORESIST COMPOSITION AND METHOD OF MANUFACTURING SEMICONDUCTOR DEVICE USING THE SAME

(71) Applicants: Samsung Electronics Co., Ltd., Suwon-si (KR); UIF (University Industry Foundation), Yonsei University, Seoul (KR)

(72) Inventors: Chawon Koh, Suwon-si (KR); Youngmin You, Seoul-si (KR); Tsunehiro Nishi, Suwon-si (KR); Ji Young Park, Suwon-si (KR); Sihyun Woo, Seoul-si (KR)

(21) Appl. No.: 18/980,106

(22) Filed: Dec. 13, 2024

(30) Foreign Application Priority Data
Jan. 15, 2024 (KR) 10-2024-0006304

(51) Int. Cl. G03F 7/004; G03F 7/38; H01L 21/027

(52) U.S. Cl. CPC G03F 7/0042; G03F 7/38; H01L 21/0275

(57) ABSTRACT

The inventive concept provides a photoresist composition containing an organometallic compound represented by General Formula 1 and a solvent,

(MR¹¹R¹²)ₐ(L)_{b}(OB)_{c}, [General Formula 1]

wherein, in General Formula 1, M is a central metal, R¹¹ and R¹² are each independently selected from an alkyl group, an aryl group, a heteroaryl group, an allyl group, an alkoxy group, an amino group, a sulfido group, and a halogen group, L is an organic ligand that is a polydentate ligand containing two hydrophobic moieties interconnected by a bridge moiety, B is selected from a hydrogen atom, an alkyl group, and an aryl group, or is omitted, a is an integer between 1 and 8, b is an integer between 1 and 4, c is an integer between 0 and 4, a sum of b and c is an integer between 1 and 4.

### CROSS-REFERENCE TO RELATED APPLICATION

This application claims priority under 35 U.S.C. § 119 to Korean Patent Application No. 10-2024-0006304, filed on Jan. 15, 2024, in the Korean Intellectual Property Office, the disclosure of which is incorporated by reference herein in its entirety.

### FIELD

The inventive concept relates to a photoresist composition and a method of manufacturing a semiconductor device using the same. More particularly, the inventive concept relates to a photoresist composition including a metal and a method of manufacturing a semiconductor device using the same.

### BACKGROUND

Advances in electronics technology have led to the rapid down-scaling of semiconductor devices. Accordingly, a photolithography process that is advantageous for implementing fine patterns is desired. In particular, there is a need to develop a photoresist composition that can provide process stability, excellent etch resistance, and resolution in a photolithography process for manufacturing a semiconductor device.

### SUMMARY

The inventive concept provides a photoresist composition with improved storage stability while providing excellent etch resistance and resolution in a photolithography process for manufacturing a semiconductor device.

Also, the inventive concept provides a method of manufacturing a semiconductor device that may improve the dimensional precision of a pattern to be formed by providing excellent etch resistance and resolution in the photolithography process.

According to an aspect of the inventive concept, there is provided a photoresist composition including an organometallic compound represented by General Formula 1 and a solvent:

(MR¹¹R¹²)ₐ(L)_{b}(OB)_{c}, [General Formula 1]

wherein, in General Formula 1, M is a central metal, R¹¹ and R¹² are each independently selected from an alkyl group, an aryl group, a heteroaryl group, an allyl group, an alkoxy group, an amino group, a sulfido group, and a halogen group, L is an organic ligand that is a polydentate ligand including two hydrophobic moieties interconnected by a bridge moiety, B is selected from a hydrogen atom, an alkyl group, and an aryl group, or B may be omitted, a is an integer between 1 and 8, b is an integer between 1 and 4, c is an integer between 0 and 4, and a sum of b and c is an integer between 1 and 4.

According to another aspect of the inventive concept, there is provided a photoresist composition including an organometallic compound represented by General Formula 1, a photoinitiator, and a solvent:

(MR¹¹R¹²)ₐ(L)_{b}(OB)_{c}, [General Formula 1]

wherein, in General Formula 1, M is Sn, R¹¹ and R¹² are each independently selected from an alkyl group, an aryl group, a heteroaryl group, an allyl group, an alkoxy group, an amino group, a sulfido group, and a halogen group, L is an organic ligand that is a polydentate ligand containing two hydrophobic moieties interconnected by a bridge moiety, B is selected from a hydrogen atom, an alkyl group, and an aryl group, or B may be omitted, a is an integer between 1 and 8, b is an integer between 1 and 4, c is an integer between 0 and 4, a sum of b and c is an integer of 1 to 4, L is represented by General Formula 2:

*-(A₁)-(L₁)-(R₁)-(L²)-(A²)-*. [General Formula 2]

In General Formula 2, A¹ and A² are each independently a carboxyl group, L¹ and L² are each independently a hydrophobic moiety that is a C5 to C10 heteroaryl group including a nitrogen atom as a hetero atom, R¹ is a bridge moiety selected from C1 to C4 straight alkyl group, C1 to C4 branched alkyl group, C2 to C4 alkenyl group, and C2 to C4 alkynyl group, and * is the connection position with the central metal.

According to another aspect of the inventive concept, there is provided a method of manufacturing a semiconductor device including forming a photoresist film on a substrate using a photoresist composition including an organometallic compound represented by General Formula 1 and a solvent, exposing a first region that is a portion of the photoresist film, baking the photoresist film including the exposed first region to form a metal structure network in the first region, and developing the photoresist film on which the metal structure network is formed to form a photoresist pattern made of the metal structure network.

### BRIEF DESCRIPTION OF THE DRAWINGS

Embodiments of the inventive concept will be more clearly understood from the following detailed description taken in conjunction with the accompanying drawings in which:

FIG. 1 is a flowchart for explaining a method of manufacturing a semiconductor device according to an example embodiment; and

FIGS. 2 to 6 are cross-sectional views for explaining a method of manufacturing a semiconductor device according to example embodiments.

### DETAILED DESCRIPTION OF THE EMBODIMENTS

Hereinafter, embodiments of the inventive concept are described in detail with reference to the attached drawings. The same reference numerals are used for the same components in the drawings, and the descriptions already given for the components are omitted.

Photoresist compositions according to embodiments may include an organometallic compound represented by General Formula 1 and a solvent:

(MR¹¹R¹²)ₐ(L)_{b}(OB)_{c}, [General Formula 1]

wherein, in General Formula 1, M is a central metal, R¹¹ and R¹² are each independently selected from an alkyl group, an aryl group, a heteroaryl group, an allyl group, an alkoxy group, an amino group, a sulfido group, and a halogen group, L is an organic ligand that is a polydentate ligand including two hydrophobic moieties interconnected by a bridge moiety, B is selected from a hydrogen atom, an alkyl group, and an aryl group, or B may be omitted, a is an integer between 1 and 8, b is an integer between 1 and 4, c is an integer between 0 and 4, and a sum of b and c is an integer between 1 and 4.

The polydentate ligand may refer to a ligand having multiple binding sites for the central metal M, for example, a bidentate ligand may refer to a ligand having two binding sites for the central metal M, a tridentate ligand may refer to a ligand that has three binding sites for the central metal M, and a tetradentate ligand may refer to a ligand that has four binding sites for the central metal M.

In some embodiments, at least one organic ligand may be a bidentate ligand.

In some embodiments, at least one organic ligand may be a tridentate ligand or a tetradentate ligand.

In some embodiments, the organic ligand may be represented by the following General Formula 2:

*-(A₁)-(L₁)-(R₁)-(L²)-(A²)-*. [General Formula 2]

In General Formula 2, A¹ and A² are each independently a carboxyl group, L¹ and L² may be each independently a hydrophobic moiety selected from a C3 to C30 heteroaryl group, a C2 to C10 heterocycloalkyl group, and a C2 to C10 heterocycloalkene group, R¹ is a bridge moiety selected from a C1 to C12 straight alkyl group, a C1 to C12 branched alkyl group, a C2 to C12 alkenyl group, and a C2 to C12 alkynyl group, and * is a connection position with the central metal M.

In some embodiments, L¹ and L² of General Formula 2 may each be a hydrophobic moiety including a nitrogen atom as a hetero atom.

In some embodiments, L¹ and L² of General Formula 2 each independently include a structure selected from pyrrole, pyrazole, imidazole, pyridine, pyrimidine, pyridazine, triazine, and derivatives thereof.

In some embodiments, R¹ may be a bridge moiety selected from a C1 to C4 linear alkyl group, a C1 to C4 branched alkyl group, a C2 to C4 alkenyl group, and a C2 to C4 alkynyl group.

In some embodiments, the at least one central metal may include at least one metal element selected from Sn, Sb, In, and Bi, Ag, Te, Au, Pb, Zn, Ti, Hf, Zr, Al, V, Cr, Co, Ni, Cu, Ga, Mn, Cu, Sr, W, Cd, Mo, Ta, Nb, Cs, Ba, La, Ce, and Fe. For example, the at least one central metal may be Sn.

In some embodiments, in General Formula 1, a may be 1, b may be 1, and c may be 0.

In some embodiments, in General Formula 1, a may be 2, b may be 1 or 2, and c may be 0 or 1.

In some embodiments, in General Formula 1, a may be 4, b may be 1 or 2, and c may be 1 or 2.

In some embodiments, the organometallic compound may include at least one structure selected from the following structures.

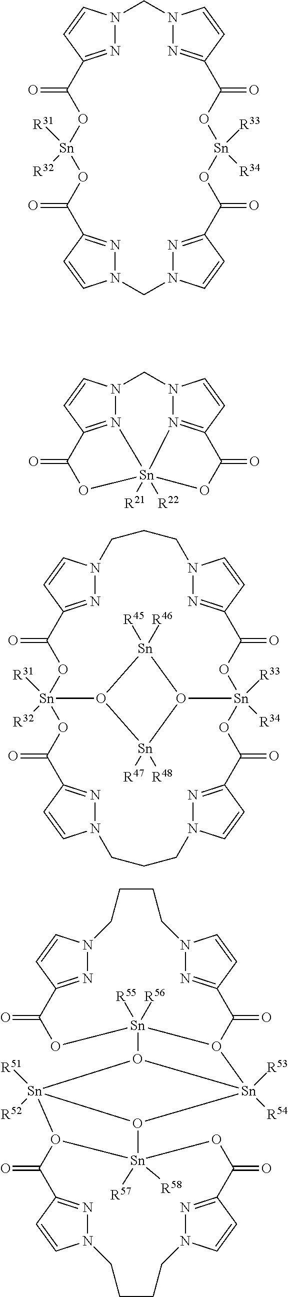

wherein, in the structural formulas R21, R22, R31, R32, R33, R34, R41, R42, R43, R44, R45, R46, R47, R48, R51, R52, R53, R54, R55, R56, R57 and R58 are each independently selected from an alkyl group, an aryl group, a heteroaryl group, an allyl group, an alkoxy group, an amino group, a sulfido group, and a halogen group. In some embodiments, they are each independently selected from an alkyl group, an aryl group, a heteroaryl group, an allyl group, and an alkoxy group. In some embodiments, they are each independently selected from amino groups, sulfido groups, and halogen groups.

In the photoresist composition according to some embodiments, the central metal may be included in an amount of about 0.1 wt % to about 30 wt % based on the total weight of the photoresist composition. For example, the central metal may range from about 0.1 wt % to about 25 wt %, from about 1 wt % to about 20 wt %, from about 1 wt % to about 15 wt %, or from about 1 wt % to about 10 wt %, or any range therein, based on the total weight of the photoresist composition.

The organometallic compound included in the photoresist composition according to some embodiments may include an organic ligand that is a polydentate ligand including two hydrophobic moieties interconnected by a bridge moiety. In some embodiments, the two hydrophobic moieties included in the organic ligand may inhibit the reaction between the organometallic compound and external elements (e.g., moisture). In some embodiments, inhibiting the reaction between the organometallic compound and external elements can improve the storage stability of the photoresist composition including the organometallic compound.

In addition, in some embodiments, by controlling the content of the central metal included in the organometallic compound by adjusting the carbon chain length of the bridge moiety connecting the two hydrophobic moieties, the crosslinking reaction of the organometallic compound by extreme ultraviolet (EUV) light (e.g., 13.5 nm) may be promoted, and thus excellent etching resistance and resolution are provided in the photolithography process, thereby improving the dimensional precision of the pattern to be formed.

In some embodiments, the photoresist composition may include a photoinitiator. The photoinitiator may generate acid or radicals by absorbing light in the exposed region of the photoresist film after the photoresist film obtained from the photoresist composition is exposed. The acid or radical generated from the photoinitiator may react with the organic ligand of the organometallic compound to induce a dissociation reaction of the organic ligand. Therefore, when the photoinitiator is included in the photoresist composition according to some embodiments, desorption of organic ligands from the organometallic compound may occur due to acids or radicals generated from the photoinitiator, and in a subsequent bake process or exposure process, a network (hereinafter referred to as “metal structure network”) consisting of a cross-linked structure including a plurality of central metals (M) may be formed densely.

The photoinitiator included in the photoresist composition according to some embodiments may compensate for the relatively low reactivity of the organometallic compound when the photoresist film obtained from the photoresist composition is exposed to light, and light sensitivity in the exposed region of the photoresist film may be adjusted (e.g., tuned) by the content of the photoinitiator. In some embodiments, the photoinitiator may induce a photoreaction limited to the exposed region of the photoresist film by promoting a ligand dissociation reaction in the organometallic compound using an acid or radical generated from the photoinitiator.

The photoinitiator may include a photoacid generator (PAG) configured to generate an acid by light, a photoradical generator (PRG) configured to generate a radical by light, or a combination of the PAG and the PRG.

The PAG may generate acid when exposed to any suitable light, e.g., selected from a KrF excimer laser (248 nm), ArF excimer laser (193 nm), F2 excimer laser (157 nm), and EUV laser (13.5 nm). In some embodiments, the PAG may include triarylsulfonium salts, diaryliodonium salts, sulfonates, or mixtures thereof. For example, the PAG may be made of triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate dicarboximide-nonaflate), triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or mixtures thereof, but is not limited thereto.

When the PRG is exposed to any one light selected from a KrF excimer laser (248 nm) and an ArF excimer laser (193 nm), F2 excimer laser (157 nm), and EUV laser (13.5 nm), the PRG may initiate polymerization of the organometallic compound included in the photoresist composition according to the embodiments by absorbing the light and generating radicals. In some embodiments, the PRG may include an acylphosphine oxide-based compound, and/or an oxime ester-based compound.

Examples of the acylphosphine oxide-based compound may include 2,4,6-trimethylbenzoyl-diphenylphosphine oxide, bis(2,4,6-trimethylbenzoyl)-phenylphosphine oxide), bis(2,6-dimethoxybenzoyl)-(2,4,4-trimethylpentyl)phosphine oxide, and the like.

Examples of the oxime ester-based compounds may include 1-phenylpropane-1,2-dione-2-(O-ethoxycarbonyl)oxime, 1-phenylbutane-1,2-dione-2-(O-methoxycarbonyl)oxime), 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[1-(2,2-dimethyl-1,3-dioxolane-4-yl)methyloxy]benzoyl]-9H-carbazol-3-yl]ethanone-1-(O-acetyl)oxime), and the like.

In other embodiments, as the PRGs, commercially available products such as IRGACURE® 651 and IRGACURE® 184, IRGACURE® 2959, IRGACURE® 127, IRGACURE® 907, IRGACURE® 369, IRGACURE® 379, IRGACURE® TPO, IRGACURE® 819, IRGACURE® OXE01, IRGACURE® OXE02, IRGACURE® MBF, or IRGACURE® 754 (BASF product, brand name) may be used.

The resist composition according to the inventive concept may include solely a single material selected from the PAG and the PRG as the photoinitiator, or may include at least two materials selected from the PAG and the PRG. In some embodiments, in the photoresist composition according to the embodiments, the photoinitiator may be included in an amount of about 0.02 mol % to about 10 mol % based on the total amount of the organometallic compound, but the inventive concept is not limited thereto.

The solvent included in the photoresist composition may be an organic solvent. The organic solvent may include at least one of ether, alcohol, glycol ether, aromatic hydrocarbon compound, ketone, and ester, but is not limited to these. For example, the organic solvent may be ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, hydroxyacetic acid. ethyl, 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl Acetate, 1-methoxy-2-propyl acetate, methoxyethoxy propionate, ethoxyethoxy propionate, or a combination thereof.

In the photoresist composition according to some embodiments, the solvent may be included in the remaining amount excluding the contents of the main components including the organometallic compound and the photoinitiator. In some embodiments, the solvent may be included in an amount of about 0.1 wt % to about 99.8 wt % or any range therein, based on the total weight of the photoresist composition, but the inventive concept is not limited thereto.

In some embodiments, when the photoresist composition according to embodiments includes the PAG as the photoinitiator, the photoresist composition may further include a basic quencher.

When an acid generated from the PAG included in the photoresist composition according to the embodiments or an acid generated from other photodegradable compounds diffuses into the unexposed region of the photoresist film, the basic quencher may include a compound capable of trapping the acid in the unexposed region. By including the basic quencher in the photoresist composition according to the embodiments, the diffusion rate of acid in the photoresist film obtained from the photoresist composition may be suppressed.

In some embodiments, the basic quencher may include a primary aliphatic amine, a secondary aliphatic amine, a tertiary aliphatic amine, an aromatic amine, a heteroaromatic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. For example, the basic quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or combinations thereof, but is not limited thereto.

In other embodiments, the basic quencher may be composed of a photobase generator. The photobase generator may generate a base by absorbing active energy rays through light irradiation and decomposing its chemical structure. Therefore, when a partial region of the photoresist film formed from the photoresist composition including the basic quencher consisting of the photobase generator is exposed, the photobase generator traps acid in the exposed region of the photoresist film, thereby controlling the sensitivity in the exposed region and suppressing diffusion of the acid from the exposed region to the non-exposed region. Accordingly, a metal structure network made of a metal oxide may be formed, wherein the metal oxide selectively includes the central metal only in the exposed area of the photoresist film. In some embodiments, the problem of adverse effects caused by unwanted diffusion of the acid, for example, problems such as deterioration of critical dimension (CD) distribution at the edge of the photoresist pattern obtained after the development process, may be minimized or prevented.

The material constituting the photobase generator is not particularly limited as long as the material generates a base by irradiation with light. In some embodiments, the photobase generator may be a non-ionic photobase generator. In other embodiments, the photobase generator may include an ionic photobase generator.

In some embodiments, the photobase generator may include a carboxylate or sulfonate salt of a photodegradable cation. For example, the photodecomposable cation included in the photobase generator may include a sulfonium cation. The sulfonium cation may include a substituted or unsubstituted C1 to C12 alkyl group, a substituted or unsubstituted C3 to C12 cycloalkyl group, a C6 to C30 aryl group, or a C3 to C30 heteroaryl group. The alkyl group, the cycloalkyl group, the aryl group, and the heteroaryl group may include at least one hetero atom selected from an O atom, an S atom, and an N atom. For example, the sulfonium cation may include, but is not limited to, a phenyl group, cyclopentyl group, cyclohexyl group, adamantyl group, methyl group, ethyl group, propyl group, butyl group, t-butyl group, or isopropyl group.

The photodegradable cation included in the photobase generator may form a complex with the anion of C1 to C20 carboxylic acid. The carboxylic acid may be, for example, formic acid, acetic acid, propionic acid, tartaric acid, succinic acid, cyclohexylcarboxylic acid, benzoic acid, or salicylic acid, but is not limited thereto.

In some embodiments, as the photobase generator, triphenylsulfonium heptafluorobutyric acid or triphenyl sulfonium hexafluoroantimonate (TPS-SbF6) may be used, but is not limited thereto.

In the resist composition according to the inventive concept, the basic quencher may be used alone, or two or more types may be mixed. The basic quencher may be included in an amount of about 0 mol % to about 50 mol % based on the total weight of the organometallic compound, but the inventive concept is not limited thereto.

In some embodiments, when the photoresist composition according to embodiments includes PRG as the photoinitiator, the photoresist composition may further include a radical quencher capable of trapping radicals.

In some embodiments, the radical quencher may include a quinone type free radical, or a nitroxide (IUPAC name: aminoxyl) free radical.

The quinone-type free radical may include p-benzoquinone, hydroquinone (1,4-dihydroxybenzene), hydroquinone monomethyl ether (4-methoxyphenol), hydroquinone monomethyl ether, hydroquinone monophenyl ether, mono-t-butyl hydroquinone (MTBHQ), di-t-butyl hydroquinone, di-t-amyl hydroquinone, toluhydroquinone, p-benzoquinone, p-benzoquinone dioxime, 2,6-dichloro-1,4-benzoquinone, 2,3,5,6-tetramethyl-1,4-benzoquinone, 2,5-dichloro-3,6-dihydroxy-p-benzoquinone, methyl-p-benzoquinone, 6-anilinoquinoline-5,8-quinone, pyrroloquinoline quinone, 2-allyl-6-methoxybenzo-1,4-quinone, or a combination thereof, but is not limited thereto.

The nitroxide free radical may include di-tert-butyl nitroxide (DTBN), 2,2,6,6-tetramethyl-1-peperidine 1-oxyl (TEMPO), 4-oxo-2, 2, 6, 6-tetramethyl-1-peperidine 1-oxyl (Oxo TEMPO), 1,1,3,3-tetraethylisoindolin-N-oxyl, N-tert-butyl-N-[1-(diethoxyphosphoryl)-2,2-dimethylpropyl]aminoxyl (SG1), N-tert-butyl-N-(2-methyl-1-phenylpropyl) aminoxyl (TIPNO), or a combination thereof, but is not limited thereto.

When performing a photolithography process using the photoresist composition according to some embodiments of the inventive concept, the radicals generated from the PRG in the exposed region of the photoresist film obtained from the photoresist composition are quenched by the radical quencher, thereby enabling sensitivity adjustment in the exposed region, and radicals flowing from the exposed region to the non-exposed region may be quenched by a radical quencher. Accordingly, a network made of a metal oxide may be formed, wherein the metal oxide selectively includes the central metal only in the exposed region. In some embodiments, the problem of adverse effects caused by unwanted diffusion of the acid, for example, problems such as deterioration of CD distribution at the edge of the photoresist pattern obtained after the development process, may be minimized or prevented.

In the resist composition according to the inventive concept, the radical quencher may be used alone, or two or more types may be mixed. The radical quencher may be included in an amount of about 0 mol % to about 50 mol %, or any range therein, based on the total weight of the organometallic compound, but is not limited thereto.

In some embodiments, photoresist compositions according to some embodiments may further include at least one selected from a leveling agent, a crosslinking accelerator, a surfactant, a dispersant, a moisture absorbent, and a coupling agent.

The leveling agent may be used to improve coating flatness when coating the photoresist composition on a substrate, and a known leveling agent available commercially may be used.

The crosslinking accelerator may include a radical polymerization initiator. The radical polymerization initiator may include a photo polymerization initiator that promotes the initiation of radical polymerization by light or a thermal polymerization initiator that promotes the initiation of radical polymerization by heat. The radical polymerization initiator is not particularly limited, but for example, a ketone-based photopolymerization initiator, an organic peroxide-based polymerization initiator, or an azo-based polymerization initiator may be used. When the photoresist composition includes the crosslinking accelerator, the crosslinking accelerator may be included in an amount of about 0.001 wt % to about 10 wt %, or any range therein, based on the total weight of the photoresist composition.

The surfactant may improve coating uniformity and wettability of the photoresist composition. In some embodiments, the surfactant may be composed of sulfuric acid ester salt, sulfonate salt, phosphoric acid ester, soap, amine salt, quaternary ammonium salt, polyethylene glycol, alkylphenolethylene oxide adduct, polyhydric alcohol, nitrogen-containing vinyl polymer, or a combination thereof, but is not limited thereto. For example, the surfactant may include alkylbenzenesulfonate, alkylpyridinium salt, polyethylene glycol, or quaternary ammonium salt. When the photoresist composition includes the surfactant, the surfactant may be included in an amount of about 0.001 wt % to about 3 wt %, or any range therein, based on the total weight of the photoresist composition.

The dispersing agent may ensure that each component constituting the photoresist composition is uniformly dispersed within the photoresist composition. In some embodiments, the dispersant may be composed of epoxy resin, polyvinyl alcohol, polyvinyl butyral, polyvinylpyrrolidone, glucose, sodium dodecyl sulfate, sodium citrate, oleic acid, linoleic acid, or a combination thereof, but is not limited thereto. When the photoresist composition includes the dispersant, the dispersant may be included in an amount of about 0.001 wt % to about 5 wt %, or any range therein, based on the total weight of the photoresist composition.

The moisture absorbent may prevent adverse effects caused by moisture in the photoresist composition. In some embodiments, the moisture absorbent may be made of polyoxyethylene nonylphenolether, polyethylene glycol, polypropylene glycol, polyacrylamide, or a combination thereof, but is not limited thereto. When the photoresist composition includes the moisture absorbent, the moisture absorbent may be included in an amount of about 0.001 wt % to about 10 wt % or any range therein based on the total weight of the photoresist composition.

The coupling agent may improve adhesion to the lower film when coating the photoresist composition on the lower film. In some embodiments, the coupling agent may include a silane coupling agent. The silane coupling agent may be composed of vinyltrimethoxysilane, vinyltriethoxysilane, vinyltrichlorosilane, vinyltris(β-methoxyethoxy) silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane, but is not limited thereto. When the photoresist composition includes the coupling agent, the coupling agent may be included in an amount of about 0.001 wt % to about 5 wt % or any range therein based on the total weight of the photoresist composition.

In the photoresist composition according to some embodiments, when the solvent consists only of an organic solvent, the photoresist composition may further include water. In this case, the water content in the photoresist composition may be about 0.001 wt % to about 0.1 wt % or any range therein.

Hereinafter, a method of manufacturing an integrated circuit device using a photoresist composition according to embodiments is described using specific examples.

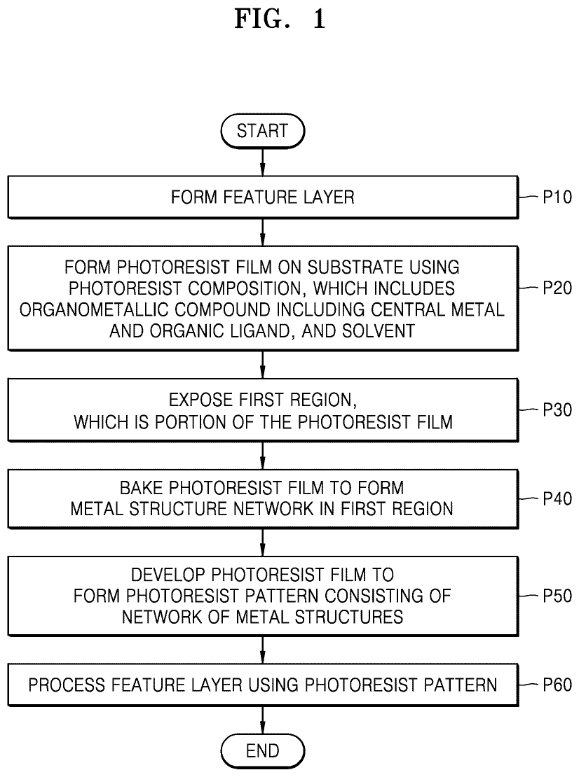

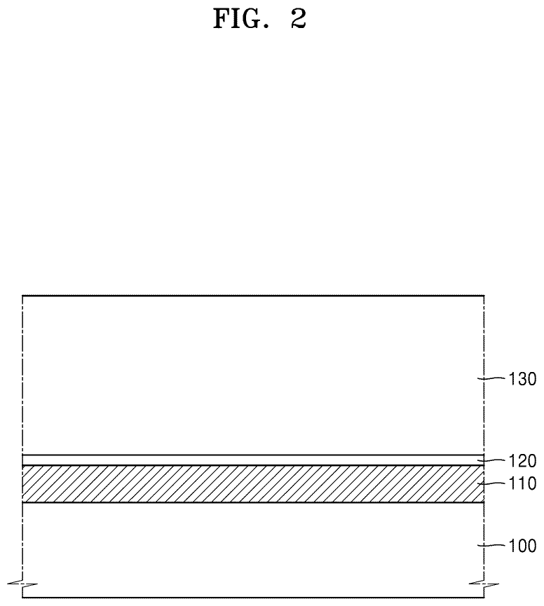

FIG. 1 is a flowchart for explaining a method of manufacturing a semiconductor device according to an embodiment. FIGS. 2 to 6 are cross-sectional views for explaining a method of manufacturing a semiconductor device according to embodiments.

Referring to FIGS. 1 and 2, in process P10, a feature layer 110 may be formed on the substrate 100, and in process P20, a photoresist film 130 may be formed on the feature layer 110 using a photoresist composition according to the inventive concept. The photoresist film 130 may include an organometallic compound, which is a component of the photoresist composition. A more detailed structure of the photoresist composition is as described above.

The substrate 100 may include a semiconductor substrate. The feature layer 110 may be an insulating film, a conductive film, or a semiconductor film. For example, the feature layer 110 may be made of metal, alloy, metal carbide, metal nitride, metal oxynitride, metal oxycarbide, semiconductor, polysilicon, oxide, nitride, oxynitride, or a combination thereof, but is not limited thereto.

According to some embodiments, before forming the photoresist film 130 on the feature layer 110, a developable bottom anti-reflective coating (DBARC) film 120 may be formed on the feature layer 110. In this case, the photoresist film 130 may be formed on the DBARC film 120. The DBARC film 120 may control diffuse reflection of light from a light source used during an exposure process for manufacturing an integrated circuit device, or may absorb reflected light from the lower feature layer 110. According to embodiments, the DBARC film 120 may be made of an organic anti-reflective coating (ARC) material for KrF excimer lasers, ArF excimer lasers, EUV resistors, or any other light source. According to embodiments, the DBARC film 120 may include an organic component having a light-absorbing structure. The light absorption structure may be, for example, a hydrocarbon compound having one or more benzene rings or a structure in which benzene rings are fused. The DBARC film 120 may be formed to have a thickness of about 20 nm to about 100 nm, or any range therein, but is not limited thereto.

To form the photoresist film 130, a photoresist composition according to the inventive concept may be coated on the DBARC film 120 and then heat treated. The coating may be performed by methods such as spin coating, spray coating, and deep coating. The process of heat treating the photoresist composition may be performed at a temperature of about 80° C. to about 300° C. for about 10 seconds to about 100 seconds, but is not limited thereto. The thickness of the photoresist film 130 may be tens to hundreds of times the thickness of the DBARC film 120. The photoresist film 130 may be formed to have a thickness of about 100 nm to about 6 m, but is not limited thereto.

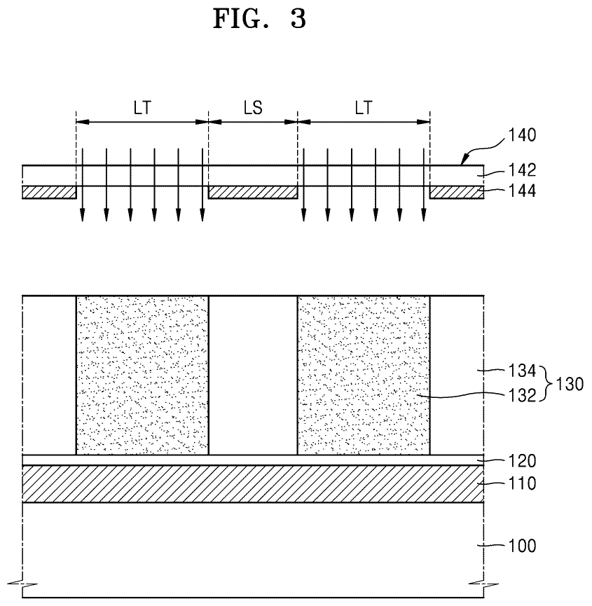

Referring to FIGS. 1 and 3, in process P30, the first region 132, which is a portion of the photoresist film 130, may be exposed.

While the photoresist film 130 is exposed, the organic metal compound included in the photoresist film 130 may be crosslinked in the first region 132 of the photoresist film 130, so that a network of metal structures may be densely formed. Accordingly, the difference in solubility in the developer between the exposed first region 132 and the unexposed second region 134 of the photoresist film 130 may increase.

According to the inventive concept, the organometallic compound of the photoresist composition used to form the photoresist film 130 may include two hydrophobic moieties interconnected by a bridge moiety and an organic ligand that is a polydentate ligand having multiple binding sites for the central metal M, so that the photoresist composition may be prevented from reacting with moisture in the air or in equipment during storage before forming a photoresist film 130 or in the process of forming the photoresist film 130, and as a result, the dimensional accuracy of the pattern to be formed may be improved.

To expose the first region 132 of the photoresist film 130, aligning a photomask 140 having a plurality of light shielding areas (LS) and a plurality of light transmitting areas (LT) at a predetermined position on the photoresist film 130, and the first region 132 of the photoresist layer 130 may be exposed through the plurality of light transmitting regions LT of the photomask 140. To expose the first region 132 of the photoresist film 130, a KrF excimer laser (248 nm), ArF excimer laser (193 nm), F2 excimer laser (157 nm), or EUV laser (13.5 nm) may be used.

The photomask 140 may include a transparent substrate 142 and a plurality of light blocking patterns 144 formed in a plurality of light blocking areas LS on the transparent substrate 142. The transparent substrate 142 may be made of quartz. The plurality of light blocking patterns 144 may be made of chrome (Cr). A plurality of light transmitting areas LT may be defined by a plurality of light blocking patterns 144. According to the inventive concept, a reflective photomask (not shown) for EUV exposure may be used instead of the photomask 140 to expose the first region 132 of the photoresist film 130.

After exposing the first region 132 of the photoresist layer 130, the photoresist layer 130 may be annealed. The annealing may be performed at a temperature of about 50° C. to about 200° C. for about 10 seconds to about 100 seconds, but is not limited thereto.

Meanwhile, after the process P30 is performed, in process P40, a bake process of applying heat to the exposed first area 132 may be performed. The bake process may be performed at a temperature of about 50° C. to about 400° C. for about 10 seconds to about 150 seconds. For example, the bake process may be performed at a temperature of about 150° C. to about 250° C. for about 60 seconds to about 120 seconds, but is not limited thereto. When the process P40 is performed, a dense metal structure network may be formed in the exposed first region 132. On the other hand, a metal structure network is not formed in the second region 134, which is an unexposed region of the photoresist film 130, and accordingly, the difference in solubility in the developer between the first region 132 and the second region 134 of the photoresist film 130 may increase.

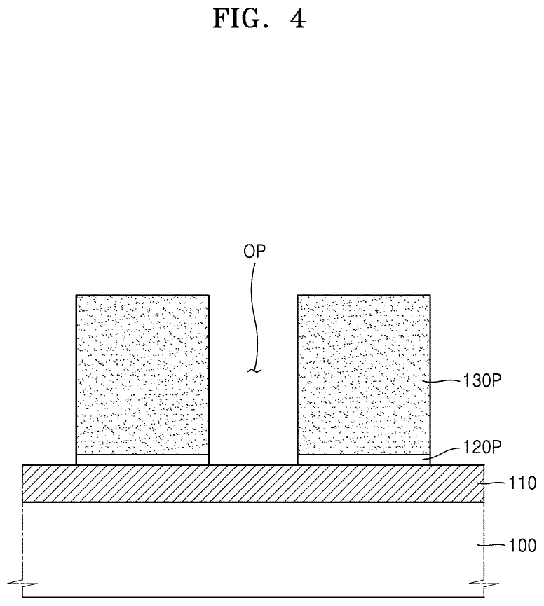

Referring to FIGS. 1 and 4, in process P50, the exposed photoresist film 130 may be developed to form a photoresist pattern 130P.

According to embodiments, the exposed photoresist film 130 illustrated in FIG. 3 may be developed to remove the unexposed second region 134 of the photoresist film 130 and form a photoresist pattern 130P consisting of the exposed first region 132 of the photoresist film 130. The photoresist pattern 130P may include a plurality of openings OP. The DBARC pattern 120P may be formed by removing the portion of the DBARC film 120 exposed through the plurality of openings OP.

According to embodiments, developing the photoresist film 130 may be performed using a negative-tone development (NTD) process. According to embodiments, propylene glycol methyl ether (PGME) may be used as a developer to develop the exposed photoresist film 130. By using the PGME as a developer, development of the photoresist film 130 including the photoresist composition according to embodiments may be smoothly performed.

In some embodiments, after the process P50 is performed to form the photoresist pattern 130P, a process of hard baking the obtained result may be further performed. Through the hard bake process, unnecessary substances such as developer remaining on the resulting photoresist pattern 130P may be removed. Additionally, as the process P50 is performed, additional reaction may be induced in unreacted portions of the photoresist pattern 130P that did not react during the process P40. Accordingly, the hardness of the photoresist pattern 130P may be further strengthened through the hard bake process. The hard bake process may be performed at a temperature of about 50° C. to about 400° C., or any temperature range therein, for about 10 seconds to about 150 seconds, or any time range therein. For example, the hard bake process may be performed at a temperature of about 150° C. to about 250° C. for about 60 seconds to about 120 seconds, but is not limited thereto.

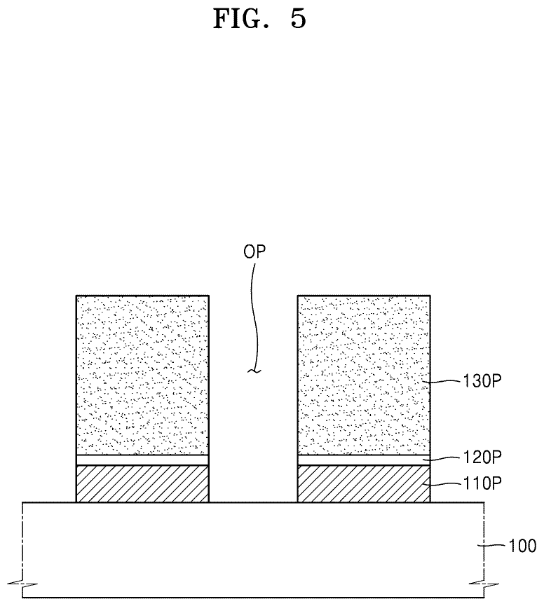

Referring to FIGS. 1 and 5, in process P60, the feature layer 110 may be processed using the photoresist pattern 130P in the result of FIG. 4.

For example, in order to process the feature layer 110, various processes may be performed, such as a process of etching the feature layer 110 exposed through the opening OP of the photoresist pattern 130P, a process of implanting impurity ions into the feature layer 110, a process of forming an additional film on the feature layer 110 through the opening OP, and a process of deforming a portion of the feature layer 110 through the opening OP. In FIG. 5, an example process for processing the feature layer 110 includes etching the feature layer 110 exposed through the opening OP to form a feature pattern 110P.

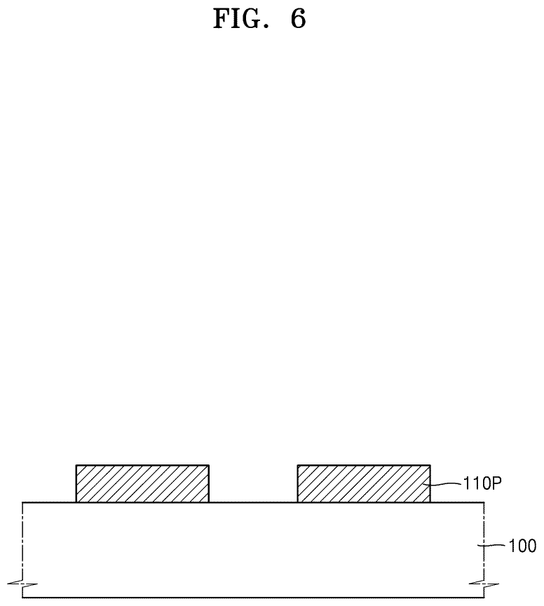

Referring to FIG. 6, in the result of FIG. 5, the photoresist pattern 130P and DBARC pattern 120P remaining on the feature pattern 110P are removed. Ashing and stripping processes may be used to remove the photoresist pattern 130P and DBARC pattern 120P.

Below, examples including specific synthesis examples are presented to aid understanding of the inventive concept, but these are only illustrative of the inventive concept and the inventive concept is not limited to the following examples.

### Synthesis Example: Preparation of Organometallic Compounds

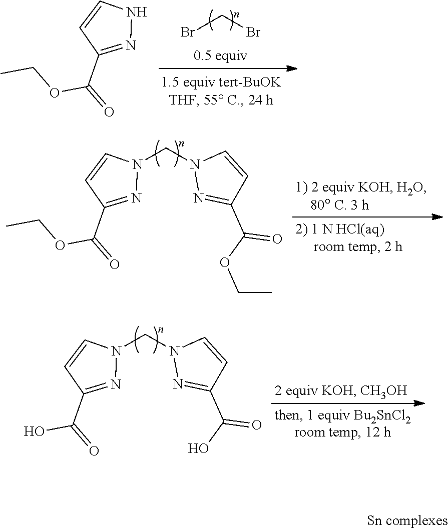

By performing a nucleophilic substitution reaction of pyrazole into which an ester group is introduced and with dibromoalkane with n of 1 to 8 in the above Synthesis Example to form bis-pyrazole, saponifying the ester group of the bis-pyrazole that has undergone a nucleophilic substitution reaction to form a carboxyl group, and reacting bis-pyrazole in which the carboxyl group was formed with dibutyltin dichloride, an organometallic compound included in the photoresist composition according to an embodiment of the inventive concept was formed.

While the inventive concept has been particularly shown and described with reference to embodiments thereof, it will be understood that various changes in form and details may be made therein without departing from the spirit and scope of the following claims.

What is claimed is:

1. A photoresist composition comprising an organometallic compound represented by General Formula 1 and a solvent,
(MR¹¹R¹²)ₐ(L)_{b}(OB)_{c}, [General Formula 1]
wherein, in General Formula 1,
M is a central metal,
R¹¹ and R¹² are each independently selected from an alkyl group, an aryl group, a heteroaryl group, an allyl group, an alkoxy group, an amino group, a sulfido group, and a halogen group,
L is an organic ligand that is a polydentate ligand containing two hydrophobic moieties interconnected by a bridge moiety,
B is selected from a hydrogen atom, an alkyl group, and an aryl group, or is omitted,
a is an integer between 1 and 8,
b is an integer between 1 and 4,
c is an integer between 0 and 4, and
a sum of b and c is an integer between 1 and 4.

2. The photoresist composition of claim 1, wherein the organic ligand includes a bidentate ligand.

3. The photoresist composition of claim 1, wherein the organic ligand includes a tridentate ligand or a tetradentate ligand.

4. The photoresist composition of claim 1, wherein the organic ligand is represented by General Formula 2:
*-(A₁)-(L₁)-(R₁)-(L²)-(A²)-*, [General Formula 2]
wherein in General Formula 2,
A¹ and A² are each independently a carboxyl group,
L¹ and L² are each independently a hydrophobic moiety selected from a C3 to C30 heteroaryl group, a C2 to C10 heterocycloalkyl group, and a C2 to C10 heterocycloalkene group,
R¹ is a bridge moiety selected from a C1 to C12 straight alkyl group, a C1 to C12 branched alkyl group, a C2 to C12 alkenyl group, and a C2 to C12 alkynyl group, and
* is a connection position with the central metal.

5. The photoresist composition of claim 4, wherein L¹ and L² are hydrophobic moieties each including a nitrogen atom as a hetero atom.

6. The photoresist composition of claim 4, wherein L¹ and L² each independently include a structure selected from pyrrole, pyrazole, imidazole, pyridine, pyrimidine, pyridazine, triazine, and derivatives thereof.

7. The photoresist composition of claim 4, wherein R¹ is a bridge moiety selected from a C1 to C4 straight alkyl group, a C1 to C4 branched alkyl group, a C2 to C4 alkenyl group, and a C2 to C4 alkynyl group.

8. The photoresist composition of claim 1, wherein the at least one central metal includes at least one metal element selected from Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Ta, Nb, Cs, Ba, La, Ce, and Fe.

9. The photoresist composition of claim 1, wherein, in General Formula 1, a is 1, b is 1, and c is 0.

10. The photoresist composition of claim 1, wherein, in General Formula 1, a is 2, b is 1 or 2, and c is 0 or 1.

11. The photoresist composition of claim 1, wherein, in General Formula 1, a is 4, b is 1 or 2, and c is 1 or 2.

12. The photoresist composition of claim 1, wherein, in General Formula 1, a is 4, b is 2, and c is 2.

13. The photoresist composition of claim 1, wherein the organometallic compound includes at least one structure selected from the following structures: 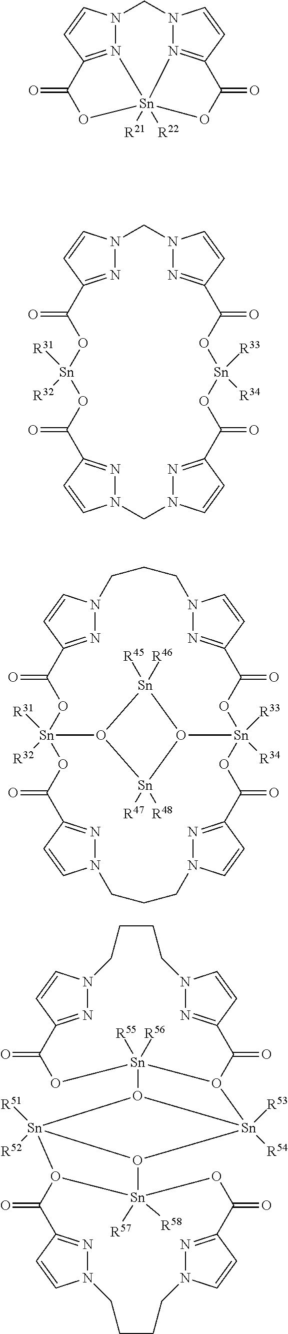
wherein, in the structural formulas, R²¹, R²², R³¹, R³², R³³, R³⁴, R⁴¹, R⁴², R⁴³, R⁴⁴, R⁴⁵, R⁴⁶, R⁴⁷, R⁴⁸, R⁵¹, R⁵², R⁵³, R⁵⁴, R⁵⁵, R⁵⁶, R⁵⁷ and R⁵⁸ may each independently be selected from an alkyl group, an aryl group, a heteroaryl group, an allyl group, an alkoxy group, an amino group, a sulfido group, and a halogen group.

14. A photoresist composition comprising an organometallic compound represented by General Formula 1, a photoinitiator, and a solvent,
(MR¹¹R¹²)ₐ(L)_{b}(OB)_{c}, [General Formula 1]
wherein, in General Formula 1,
M is Sn,
R¹¹ and R¹² are each independently selected from an alkyl group, an aryl group, a heteroaryl group, an allyl group, an alkoxy group, an amino group, a sulfido group, and a halogen group, L is an organic ligand that is a polydentate ligand containing two hydrophobic moieties interconnected by a bridge moiety,
B is selected from a hydrogen atom, an alkyl group, and an aryl group, or is omitted,
a is an integer between 1 and 8,
b is an integer between 1 and 4,
c is an integer between 0 and 4,
a sum of b and c is an integer of 1 to 4, and
L is represented by General Formula 2;
*-(A₁)-(L₁)-(R₁)-(L²)-(A²)-*, [General Formula 2]
wherein, in General Formula 2,
A¹ and A² are each independently a carboxyl group,
L¹ and L² are each independently a hydrophobic moiety that is a C3 to C30 heteroaryl group including a nitrogen atom as a hetero atom,
R¹ is a bridge moiety selected from C1 to C4 straight alkyl group, C1 to C4 branched alkyl group, C2 to C4 alkenyl group, and C2 to C4 alkynyl group, and
* is a connection position with the central metal.

15. The photoresist composition of claim 14, wherein L¹ and L² each independently include a structure selected from pyrrole, pyrazole, imidazole, pyridine, pyrimidine, pyridazine, triazine, and derivatives thereof.

16. The photoresist composition of claim 14, wherein the photoinitiator consists of a photoradical generator (PRG) configured to generate radicals in response to light.

17. The photoresist composition of claim 14, further comprising a radical quencher capable of trapping radicals.

18. A method of manufacturing a semiconductor device, the method comprising:
forming a photoresist film on a substrate using a photoresist composition including an organometallic compound represented by General Formula 1 and a solvent;
exposing a first region that is a portion of the photoresist film;
baking the photoresist film including the exposed first region to form a metal structure network in the first region; and
developing the photoresist film on which the metal structure network is formed to form a photoresist pattern made of the metal structure network;
(MR¹¹R¹²)ₐ(L)_{b}(OB)_{c}, [General Formula 1]
wherein, in General Formula 1,
M is a central metal,
R¹¹ and R¹² are each independently selected from an alkyl group, an aryl group, a heteroaryl group, an allyl group, an alkoxy group, an amino group, a sulfido group, and a halogen group,
L is an organic ligand that is a polydentate ligand including two hydrophobic moieties interconnected by a bridge moiety,
B is selected from a hydrogen atom, an alkyl group, and an aryl group, or is omitted,
a is an integer between 1 and 8,
b is an integer between 1 and 4,
c is an integer between 0 and 4, and
a sum of b and c is an integer between 1 and 4.

19. The method of claim 18, wherein L¹ and L² each independently include a structure selected from pyrrole, pyrazole, imidazole, pyridine, pyrimidine, pyridazine, triazine, and derivatives thereof.

20. The method of claim 18, wherein L¹ and L² are hydrophobic moieties each including a nitrogen atom as a hetero atom.
